(19) United States
(12) Patent Application Publication
(10) Pub. No.: US 2026/0110078 A1
(43) Pub. Date: Apr. 23, 2026

(54) CONTROLLABLE CARBON PECVD FILM DEPOSITION

(71) Applicant: Lam Research Corporation, Fremont, CA (US)

(72) Inventors: Gordon Alex MACDONALD, Sherwood, OR (US); Vineet MALIEKKAL, Beaverton, OR (US); Francis Sloan ROBERTS, Portland, OR (US); Toshisato ONO, Tualatin, OR (US); Ragesh PUTHENKOVILAKAM, Portland, OR (US); Kapu Sirish REDDY, Portland, OR (US)

(21) Appl. No.: 19/117,014

(22) PCT Filed: Oct. 23, 2023
(86) PCT No.: PCT/US2023/077509

§ 371 Date: Mar. 28, 2025

Related U.S. Application Data
(60) Provisional application No. 63/380,714, filed on Oct. 24, 2022.

(51) Int. Cl. C23C 16/04; C23C 16/26; C23C 16/509; C23C 16/52

(52) U.S. Cl. CPC C23C 16/045; C23C 16/26; C23C 16/509; C23C 16/52

(57) ABSTRACT

Examples are disclosed that relate controllably forming a carbon film on a substrate using PECVD. One example provides a method that comprises positioning the substrate within a PECVD processing chamber, supplying a gas mixture into the PECVD processing chamber that includes a carbon film precursor and one or more of a passivating agent or an etching agent, and controlling the processing chamber conditions to deposit the carbon film on the substrate by PECVD.

### BACKGROUND

Electronic device fabrication processes can involve many steps of material deposition, patterning, and removal to form integrated circuits on substrates. Various methods can be used to deposit films of materials onto a substrate. As one example, chemical vapor deposition (CVD) can be used to deposit a film by exposing a substrate to a flow of gas phase precursors. The gas phase precursors undergo chemical reactions to form a film on the substrate. Plasma-enhanced CVD (PECVD) utilizes a plasma to provide energy for the chemical conversion of the precursors to the film. CVD processes can be used to deposit a wide variety of films.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to controllably forming carbon films using plasma enhanced chemical vapor deposition (PECVD). One example provides a method comprising positioning a substrate within a PECVD processing chamber. The method further comprises supplying a gas mixture comprising a carbon film precursor, and also comprising a passivating agent, an etching agent, or the passivating agent and the etching agent, into the processing chamber. The method further comprises controlling at least one processing chamber condition to deposit a carbon film on the substrate by PECVD.

In some such examples, the substrate alternatively or additionally comprises a recessed feature extending into the substrate from an opening at a surface of the substrate, and the carbon film at least partially fills the recessed feature.

In some such examples, the recessed feature alternatively or additionally comprises a gap in a 3D NAND memory structure, and the carbon film is a carbon hardmask plug.

In some such examples, passivating agent or the etching agent alternatively or additionally comprises a hydrogen-containing molecule.

In some such examples, the hydrogen-containing molecule comprises hydrogen (H₂) or ammonia (NH₃).

In some such examples, the passivating agent or the etching agent alternatively or additionally comprises boron trifluoride (BF₃), carbon monoxide (CO), carbon dioxide (CO₂), carbon oxysulfide (COS), molecular oxygen (O₂), nitrogen trifluoride (NF₃), sulfur dioxide (SO₂), sulfur trifluoride (SF₃), sulfur hexafluoride (SF₆), a halocarbon gas, a halogen acid (hydrofluoric acid (HF), hydrochloric acid (HCl), hydrobromic acid (HBr), hydroiodic acid (HI)), a halogen gas (F₂, Cl₂, Br₂, I₂), or a combination of two or more thereof.

In some such examples, the substrate alternatively or additionally is an additional carbon layer deposited over an eroded hardmask layer.

In some such examples, the carbon film alternatively or additionally has a tapered profile.

In some such examples, controlling the chamber condition alternatively or additionally comprises applying a first radiofrequency (RF) power and a second RF power to form a plasma, wherein the first RF power has a lower frequency than the second RF power.

In some such examples, the power of the first RF power is between 100 W and 6000 W and the power of the second RF power is between 250 W and 5000 W.

In some such examples, the carbon film precursor alternatively or additionally comprises a precursor molecule that is in a gas phase in the processing chamber, the precursor molecule comprising an alkane having a general formula CₙH₂ₙ₊₂ where n=1 to 10, an alkene having a general formula CₙH₂ₙ where n=2 to 10, an alkyne having a general formula CₙH₂ₙ₋₂ where n=2 to 10 an alkyl amine, a cyclic hydrocarbon, or a combination of two or more thereof.

In some such examples, the carbon film precursor alternatively or additionally comprises acetylene, propylene, methane, or a combination of two or more thereof.

In some such examples, alternatively or additionally the thickness of the carbon film ranges from 20 nm to 1,000 nm.

In some such examples, alternatively or additionally a ratio of the carbon film precursor to the passivating agent, the etching agent, or both the passivating agent and the etching agent is 2:1 or greater.

In some such examples, alternatively or additionally, controlling at least one processing chamber condition to deposit the carbon film on the substrate comprises controlling the pressure of the processing chamber to between 0.25 Torr and 20 Torr.

Another example provides a processing tool. The processing tool comprises a processing chamber, a radiofrequency (RF) power supply, and one or more processing gas sources. The one or more processing gas sources comprise a carbon film precursor source comprising a carbon film precursor. The one or more processing gas sources further comprise a passivating agent source comprising a passivating agent, an etching agent source comprising an etching agent, or the passivating agent source and the etching agent source. The processing tool further comprises flow control hardware fluidly connecting the one or more processing gas sources and the processing chamber. The processing tool further comprises a controller configured to control the flow control hardware to supply a gas mixture comprising the carbon film precursor and one or more of the passivating agent or the etching agent into the processing chamber, control the RF power supply to form a plasma in the processing chamber, and control at least one processing chamber condition to deposit a carbon film on a substrate situated within the processing chamber by plasma enhanced chemical vapor deposition (PECVD).

In some such examples, one or more of the passivating agent or the etching agent alternatively or additionally comprises a hydrogen-containing molecule.

In some such examples, the hydrogen-containing molecule alternatively or additionally comprises one or more of molecular hydrogen (H₂) or ammonia (NH₃).

In some such examples, the passivating agent or the etching agent alternatively or additionally comprises boron trifluoride (BF₃), carbon monoxide (CO), carbon dioxide (CO₂), carbon oxysulfide (COS), molecular oxygen (O₂), nitrogen trifluoride (NF₃), sulfur dioxide (SO₂), sulfur trifluoride (SF₃), sulfur hexafluoride (SF₆), a halocarbon gas, a halogen acid (hydrofluoric acid (HF), hydrochloric acid (HCl), hydrobromic acid (HBr), hydroiodic acid (HI)), a halogen gas (F₂, Cl₂, Br₂, I₂), or a combination of two or more thereof.

In some such examples, the controller is alternatively or additionally configured to form the plasma by controlling the RF power supply to apply a first RF power and a second RF power, wherein the first RF power has a lower frequency than the second RF power.

In some such examples, the power of the first RF power is between 100 W and 6000 W and the power of the second RF power is between 250 W and 5000 W.

In some such examples, the carbon film precursor alternatively or additionally comprises precursor molecule that is in a gas phase in the processing chamber conditions, the precursor molecule comprising one or more of an alkane having a general formula CₙH₂ₙ₊₂ where n=1 to 10, an alkene having a general formula CₙH₂ₙ where n=2 to 10, an alkyne having a general formula CₙH₂ₙ₋₂ where n=2 to 10, an alkyl amine, a cyclic hydrocarbon, or a combination of two or more thereof.

Another example provides a method of thickening a carbon hardmask layer on a substrate. The method comprises positioning the substrate within a plasma-enhanced chemical vapor deposition (PECVD) processing chamber. The substrate comprises a gap extending into the substrate from an opening in a surface of the substrate. The carbon hardmask layer is disposed on the surface of the substrate and adjacent to the gap. The method further comprises supplying a gas mixture comprising a carbon film precursor and one or more of a passivating agent or an etching agent into the processing chamber. The method further comprises controlling processing chamber conditions to deposit an additional carbon layer on the carbon hardmask layer.

In some such examples, the additional carbon layer alternatively or additionally has a tapered profile.

In some such examples, the passivating agent or the etching agent comprises hydrogen (H₂), ammonia (NH₃), boron trifluoride (BF₃), carbon monoxide (CO), carbon dioxide (CO₂), carbon oxysulfide (COS), molecular oxygen (O₂), nitrogen trifluoride (NF₃), sulfur dioxide (SO₂), sulfur trifluoride (SF₃), sulfur hexafluoride (SF₆), a halocarbon gas, a halogen acid (hydrofluoric acid (HF), hydrochloric acid (HCl), hydrobromic acid (HBr), hydroiodic acid (HI)), a halogen gas (F₂, Cl₂, Br₂, I₂), or a combination of two or more thereof.

### BRIEF DESCRIPTION OF THE DRAWINGS

FIGS. 1A-1E schematically show structures formed by an example process for increasing a thickness of a carbon hardmask layer by PECVD without using one or more of a passivating agent or an etching agent.

FIGS. 2A-2E schematically show structures formed by an example process for forming a carbon hardmask plug by PECVD without using one or more of a passivating agent or an etching agent.

FIG. 3 is a flow diagram depicting an example method of forming a carbon film on a substrate by PECVD using one or more of a passivating agent or an etching agent.

FIG. 4 shows a flow diagram depicting another example method of forming a carbon film on a substrate by PECVD using one or more of a passivating agent or an etching agent.

FIGS. 5A-5E schematically show structures formed by an example carbon hardmask plug formation process using one or more of a passivating agent or an etching agent.

FIG. 6 shows a flow diagram depicting an example method for increasing a thickness of a carbon hardmask film on a substrate by PECVD using one or more of a passivating agent or an etching agent.

FIGS. 7A-7D schematically show structures in an example process of increasing a thickness of a carbon hardmask by carbon PECVD using one or more of a passivating agent or an etching agent.

FIGS. 8A-8D schematically show structures in another example process increasing a thickness of a carbon hardmask using one or more of a passivating agent or an etching agent.

FIG. 9 shows aspects of an example plasma-enhanced chemical vapor deposition tool.

FIG. 10 shows a block diagram depicting an example computing system.

### DETAILED DESCRIPTION

The term “alkane” generally represents compounds comprising a general formula CₙH₂ₙ₊₂. Example alkanes include methane, ethane, propane, and butane. Example alkanes that may be suitable for use as a carbon film precursor as disclosed herein may comprise alkanes in which n=1 to 10.

The term “alkene” generally represents hydrocarbon compounds comprising at least one carbon-carbon double bond. Alkenes comprising one carbon-carbon double bond have a general formula of CₙH₂ₙ. Example alkenes include ethylene, propylene, and butylenes. Alkenes may have more than one carbon-carbon double bond, such as dienes, allenes, and cumulenes. Example alkenes that may be suitable for use as a carbon film precursor may comprise alkenes in which n=2 to 10.

The term “alkyl amine” generally represents hydrocarbon compounds comprising a nitrogen with 1 to 3 alkyl substituents and 0 to 2 H substituents. Alkyl amines may comprise primary, secondary, tertiary, and cyclic amines. Examples of alkyl amines suitable for use as a carbon film precursor include methylamine, dimethylamine, trimethylamine, and piperidine.

The term “alkyne” generally represents hydrocarbon compounds comprising at least one carbon-carbon triple bond. Alkynes comprising one carbon-carbon triple bond have a general formula of CₙH₂ₙ₋₂. Alkynes may have more than one carbon-carbon triple bond, such as diynes, which have two carbon-carbon triple bonds. Example alkynes that may be suitable for use as a carbon film precursor may comprise alkynes in which n=2 to 10.

The term “carbon film” generally represents a film comprising one or more forms of elemental carbon. A carbon film may comprise amorphous carbon.

The term “carbon film precursor” generally represents a carbon-containing compound that can be introduced into a processing chamber in gas phase to form a carbon film on a substrate in the processing chamber. A carbon film precursor for the PECVD process may comprise a carbon-containing gas, such as a low molecular-weight hydrocarbon. Example carbon film precursors may comprise alkanes having a general formula CₙH₂ₙ₊₂ where n is an integer in a range of 1 to 10 (such as, methane, ethane, etc.), alkenes having a general formula CₙH₂ₙ where n=2 to 10 (such as, ethylene, propylene, etc.), and alkynes having a general formula CₙH₂ₙ₋₂ where n=2 to 10 (such as, acetylene, propyne, etc.), that are gas-phase under processing conditions. Other examples of carbon film precursors may comprise cyclic hydrocarbons including aromatics, nitrogen-containing compounds including alkyl amines, and oxygen-containing compounds including alcohols, ketones, esters, aldehydes, and ethers that are gas-phase under processing conditions.

The term “chemical vapor deposition” (CVD) generally represents a process in which a solid phase film is formed on a substrate by directing a flow of one or more precursor gases over the substrate surface under conditions configured to cause the chemical conversion of the precursor gases to the solid phase film. The term “plasma-enhanced chemical-vapor deposition” (PECVD) generally represents a CVD process in which a plasma is used to facilitate the chemical conversion of one or more precursor gases to a solid phase film on a substrate. The terms “growth”, “deposition”, and variants thereof, also may be used to refer to film formation.

The term “etch stop layer” generally represents a film layer that is revealed by removal of another material in an etching process and that is more resistant to an etching process than the removed material.

The term “etching agent” generally represents any substance that may be present in a PECVD processing gas mixture to remove materials from the substrate. Example agents may include halogen-containing and/or oxygen-containing gases. Example halogen-containing etching agents may include chlorine (Cl₂), fluorine (F₂), bromine (Br₂), iodine (I₂), nitrogen trifluoride (NF₃), boron trifluoride (BF₃), sulfur trifluoride (SF₃), sulfur hexafluoride (SF₆), and halocarbon species having a general formula CₐH_{b}X_{c} species, where X comprises one or more of fluorine, chlorine, bromine, or iodine and where a=1-10). Example oxygen-containing etching agents include, but are not limited to, carbon monoxide (CO), carbon dioxide (CO₂), carbon oxysulfide (COS), sulfur dioxide (SO₂), and molecular oxygen (O₂).

The term “gap” generally represents a recessed feature that extends into a substrate from an opening in the substrate surface.

The term “gas mixture” generally represents a mixture of two or more gases in a processing chamber during a CVD process.

The term “hardmask layer” generally represents a film that is more resistant to etching than polymer photoresists. Example hardmasks include carbon films.

The term “hardmask plug” generally represents a deposit of a hardmask material that at least partially fills a gap and that protects a gap from a subsequent etching process performed above the gap.

The term “lateral growth” generally represents growth of a film along a direction parallel to a substrate surface.

The term “passivating agent” generally represents a material in a PECVD processing gas mixture that may physisorb or chemisorb to a substrate surface to reduce a rate of PECVD film formation on the substrate surface. Example passivating agents include molecules that may provide hydrogen ions and/or hydrogen radicals when exposed to a plasma. Example passivating agents that may provide hydrogen ions and/or hydrogen radicals include hydrogen-containing molecules. Example hydrogen-containing molecules that may be used as passivating agents include molecular hydrogen (H₂), and ammonia (NH₃).

The term “plasma” generally represents an ionized gas comprising gas-phase cations and free electrons.

The term “processing chamber” generally represents an enclosure in which chemical and/or physical processes are performed on substrates. The pressure, temperature, gas flow rate, and atmospheric composition within a processing chamber may be controllable to perform chemical and/or physical processes.

The term “processing chamber conditions” generally represents controllable conditions in a processing chamber of a processing tool. Examples include pressure, temperature, gas flow rate, and atmospheric composition. Controllable aspects of atmospheric composition include one or more of a gas mixture or plasma conditions.

The term “profile” generally represents a shape of a deposited film.

The term “sticking coefficient” generally represents a ratio of a number of gas-phase species that adsorb to a substrate surface compared to a number of the gas-phase species that impinge upon the substrate surface.

The term “substrate” generally represents any object onto which a film can be deposited in a processing chamber.

The term “tapered profile” generally represents a profile of additional carbon deposited on a substrate, such as an eroded hardmask layer. A tapered profile comprises a lateral narrowing of the additional carbon as a function of increasing distance from the eroded hardmask layer.

The term “vertical growth” generally represents film growth in a direction normal to a substrate surface.

The term “3D DRAM” is an acronym for three-dimensional dynamic random-access memory.

The term “3D NAND” is an acronym for three-dimensional NOT AND memory, and generally represents memory architecture based upon NOT AND logic gates.

The term “3D NOR” is an acronym for three-dimensional NOT OR memory, and generally represents memory architecture based upon NOT OR logic gates.

As mentioned above, the fabrication of electronic devices involves many steps of material deposition, patterning, and removal. For example, 3D NAND semiconductor devices utilize stacked pairs of material layers. The stack may be referred to as a “mold stack”. Patterning, etching, and metallization of the mold stack is performed to create a 3D NAND memory chip. Similar processes may be used to form 3D DRAM and 3D NOR chips. The fabrication of 3D circuit structures may involve the etching of high aspect ratio features through a mold stack. These features also may be referred to as gaps. A patterned hardmask material can be used to define the locations of the gaps. The patterned hardmask material protects surrounding substrate areas from the etching process. However, the hardmask material itself is etched, although at a lower rate than the substate materials during etching. When forming high aspect ratio gaps, a hardmask can be substantially eroded before gap formation is complete. If etching breaks through a hardmask layer, the etching process can damage the substrate. Various methods can be used to avoid damage to a substrate when etching high aspect ratio gaps. A first example method can be to deposit a thicker hardmask. However, increasing a thickness of a hardmask, followed by removing the hardmask from substrate areas that are to be etched, can pose both processing and cost problems. A second example method can be to deposit additional carbon onto an eroded hardmask layer partway through a gap etching process to thicken the eroded hardmask layer. However, the additional carbon can grow in lateral directions. As such, the additional carbon can close off the gaps being etched. This can impede further etching.

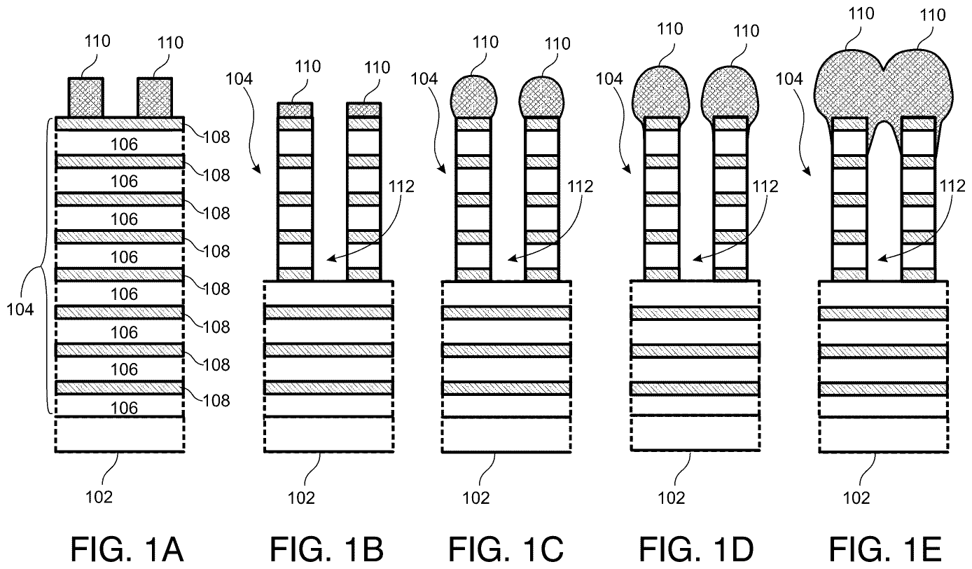

FIGS. 1A-1E illustrate closing off of a gap by depositing additional carbon to thicken a hardmask layer. First, FIG. 1A shows a substrate 102 on which a mold stack 104 is disposed along its surface. Mold stack 104 can comprise an alternating stack of layers of a first material 106 and a second material 108. Mold stack 104 can be formed in a 3D memory structure fabrication process, for example. Substrate 102 represents any suitable structures onto which an alternating stack of layers can be formed in a 3D integrated circuit fabrication process. In some examples, first material 106 can comprise an oxide, such as silicon oxide, and second material 108 can comprise a nitride, such as silicon nitride. In other examples, first material 106 can comprise silicon oxide and second material 108 can comprise polysilicon. In further examples, mold stack 104 can include an alternating stack of any other suitable first material 106 and second material 108. Mold stack 104 is topped by a hardmask 110 that defines an etching pattern. In some examples, hardmask 110 can comprise an amorphous carbon film. For ease of illustration, the labels for first material 106 and second material 108 are omitted from figures FIG. 1B-1E, and are instead represented collectively by mold stack 104.

FIG. 1B shows mold stack 104 after a partial etching process. In FIG. 1B, mold stack 104 includes a gap 112. Gap 112 can be formed using any suitable directional etching process. Examples can include plasma etch processes using etchants comprising fluorine. In FIG. 1B, gap 112 is partially complete. However, hardmask 110 has also been eroded by the etching process.

Continued etching with the eroded hardmask 110 of FIG. 1B can result in damage to mold stack 104. Thus, it can be desirable to grow additional carbon over eroded hardmask 110 to reduce the likelihood of damage to mold stack 104 and so that gap 112 can be extended by further etching.

FIGS. 1C-1E show incremental growth of additional carbon over hardmask 110 using a deposition process, such as PECVD. The carbon deposition process can result in lateral growth as well as vertical growth. This growth pattern can be at least in part due to the sticking coefficient of the carbon film precursor. The carbon deposition can partially or fully occlude the opening of gap 112 due to the lateral growth, such as that shown in FIG. 1E. Thus, the additional carbon can impede further etching within gap 112.

A third example method used to avoid damage to a substrate when etching a high aspect ratio gap for a 3D memory structure is to form the mold stack and high aspect ratio gap in stages. In a first stage, a first deck comprising a first plurality of alternating material layers is deposited (e.g., first material 106 and second material 108). A first gap is formed through the first deck. Then, a carbon hardmask plug is formed in the gap in the first deck. The hardmask plug at least partially fills the gap, and fully plugs an opening of the gap. After planarization, a second deck comprising a second plurality of alternating material layers is formed. Next, a second gap that is vertically aligned with the first gap is etched to the carbon hardmask plug. The carbon hardmask plug then is removed to join the first and second gaps. This forms a high aspect ratio gap through the first deck and the second deck. A carbon hardmask plug can be removed by ashing, for example. Additional decks can be processed similarly if desired. In this manner, a mold stack comprising a high aspect ratio gap can be formed in stages.

The carbon hardmask plug protects the first gap when the second gap etching process reaches the first gap. The carbon hardmask plug can be formed from amorphous carbon using PECVD. However, as described above, carbon film precursors used to form carbon films by PECVD can have relatively high sticking coefficients. As such, the carbon films can deposit preferentially at an upper portion of the first gap. After planarization, the resulting hardmask plug can be too thin to protect the first gap from the second gap etching process, which can lead to damage to the first deck.

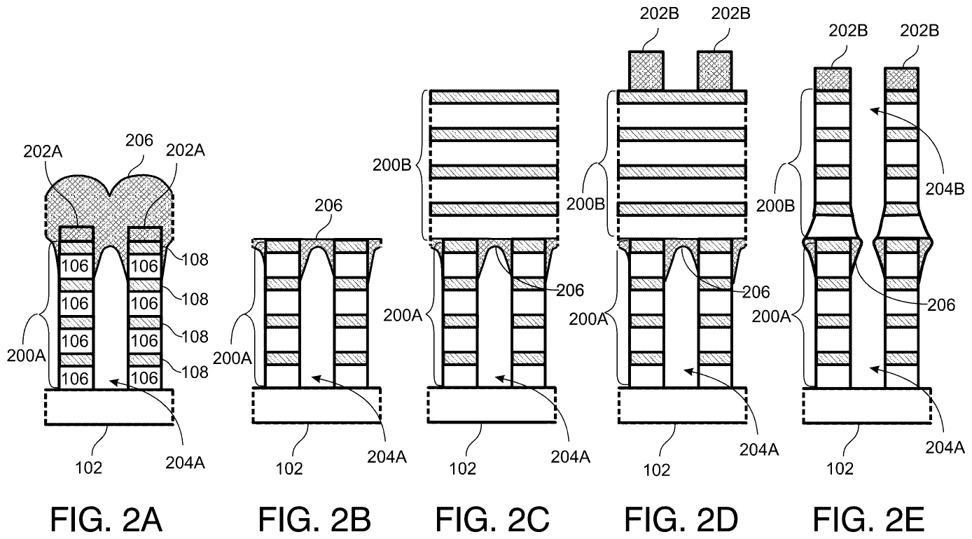

To illustrate, FIGS. 2A-2D depict structures formed by an example multi-stage mold stack deposition and etching process in which an unsuitably thin hardmask plug is formed. First, FIG. 2A shows a first deck 200A. The first deck 200A is topped by a first hardmask 202A and comprise a first gap 204A. An amorphous carbon hardmask plug 206 is deposited on first hardmask 202A and over the opening of first gap 204A. As described above in connection with FIGS. 1C-1E, a carbon film precursor can have a sticking coefficient that leads to preferential growth close to an opening of gap 204A. As a result, when forming hardmask plug 206, a relatively small amount of carbon is deposited within gap 204A. Next, planarization is performed to planarize hardmask plug 206 and remove hardmask 202 from the first deck. FIG. 2B illustrates hardmask plug 206 after planarization. Due to the sticking coefficient of the carbon film precursor used to deposit hardmask plug 206, hardmask plug 206 is relatively thin.

Referring next to FIG. 2C, in a second stage, a second deck 200B comprising a second plurality of alternating material layers is formed. Referring to FIG. 2D, a second hardmask 202B is formed and patterned on top of second deck 200B. As shown in FIG. 2E, a second gap 204B that is vertically aligned with the first gap 204A is etched. Second gap 204B is etched to a depth of hardmask plug 206. As mentioned above, hardmask plug 206 is deposited to protect first gap 204A from damage while etching second gap 204B. However, since hardmask plug 206 is relatively thin, the etching process used to form second gap 204B can break through hardmask plug 206, as illustrated in FIG. 2E. This can result in damage to first deck 200A within first gap 204A.

Alternatively, in some cases, the hardmask plug 206 may not fully form below the upper surface of first deck 200A, so that upon planarization, hardmask plug 206 can be incomplete (i.e., define an opening). This lack of an intact plug 206 can then lead to an inverted V-shaped growth of the second deck 200B when depositing second desk 200B (e.g., FIG. 2E).

Alternating cycles of carbon deposition and etching can be used to deposit a thicker hardmask plug. However, using alternating deposition and etching cycles to form a plug can be relatively inefficient and expensive.

Accordingly, examples of the disclosed technology relate to the controllable deposition of amorphous carbon films by PECVD. The disclosed examples can utilize one or more of a passivating agent or an etching agent in a carbon PECVD gas mixture. In some examples, the one or more of the passivating agent or etching agent can help to deposit a carbon film relatively more deeply within a gap to form a relatively thicker hardmask plug. In other examples, the one or more of the passivating agent or etching agent can allow an eroded hardmask layer to be thickened by depositing an additional carbon layer on the eroded hardmask layer without closing off or otherwise obstructing a gap being etched. Controllable carbon deposition according to the present disclosure can be used in any other suitable applications as well.

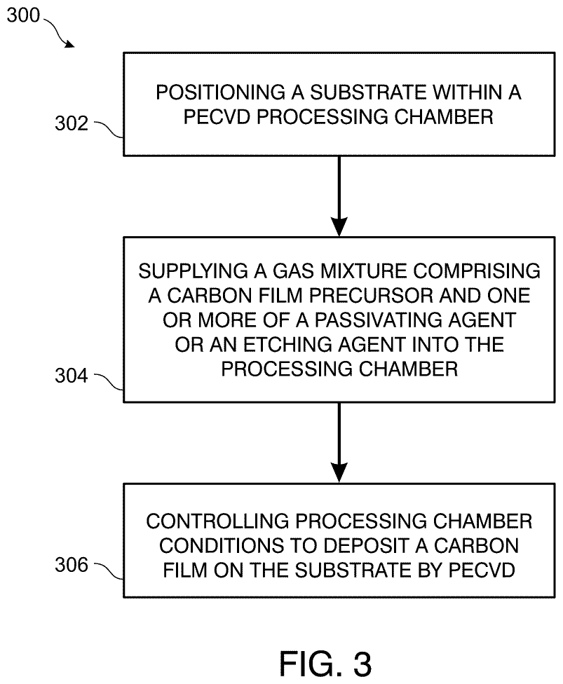

FIG. 3 shows a flow diagram depicting an example method 300 for controllably forming a carbon film on a substrate using a PECVD process comprising one or more of a passivating agent or an etching agent. Method 300 is described in the context of fabrication of a 3D memory structure. Method 300 can also be used in any other suitable integrated circuit fabrication process. It will be understood that various upstream fabrication processes can be performed prior to the forming of a carbon film on the substrate. For example, in the fabrication of a 3D memory structure, upstream processes can comprise formation of a deck of a mold stack, or formation of an entirety of a mold stack. Upstream processes also can comprise etching of a gap in the deck or etching of a gap in the mold stack.

At 302, method 300 comprises positioning a substrate within a PECVD processing chamber. At 304, method 300 comprises supplying a gas mixture comprising a carbon film precursor and one or more of a passivating agent or an etching agent into the processing chamber. The use of a passivating agent can favor carbon film growth deeper within a gap, farther from the gap opening, by inhibiting deposition of carbon less deep within the gap, closer to a gap opening. The use of an etching agent can allow a directionality of a deposition to be controlled. For example, an etching agent can be used to reduce a lateral growth rate of a carbon film relative to a vertical growth rate. Where both a passivating agent and an etching agent are used in method 300, the passivating agent and etching agent can be used simultaneously, or in sequence.

Continuing, at 306, method 300 comprises controlling one or more processing chamber conditions to deposit the carbon film on the substrate by PECVD. By forming the carbon film using a gas mixture that comprises one or more of a passivating agent or an etching agent, in combination with controlling processing chamber conditions, the resulting carbon film can be deposited onto the substrate with a desired and controllable profile. In some examples, the gas mixture and processing chamber conditions can be controlled to form a carbon hardmask plug having sufficient thickness to maintain integrity during etching of a corresponding gap in a higher deck of a mold stack. This can help to protect an etched gap in a lower deck of a mold stack. In other examples, the gas mixture and the processing chamber conditions can be controlled to deposit additional carbon on an eroded hardmask without occluding or closing off the gap. This thickens the eroded hardmask. The disclosed examples further can allow such carbon films to be deposited in a single process cycle, rather than through repeated alternating steps of deposition and etching.

Any suitable processing chamber conditions can be controlled at 306. Examples can include one or more of a substrate temperature, a processing chamber pressure, a partial mole fraction of one or more processing gases of a gas mixture, a flow rate of one or more processing gases of the gas mixture, an RF frequency or frequencies used to form an RF plasma, and/or a power of each RF frequency used to form the RF plasma.

Further, any suitable substrate temperature can be used during a carbon film deposition process. In some examples, the substrate can be heated to a temperature in a range of 25° C. to 700° C. In other examples, temperatures outside of this range can be used. In some examples, heating the substrate at a relatively higher temperature can result in the deposit of carbon relatively deeper within a gap on the substrate. In some examples, heating the substrate at a relatively lower temperature can result in greater vertical growth of deposited carbon. When heating the substrate at a relatively lower temperature, the inclusion of an etching agent and/or passivating agent in the gas mixture with the carbon film precursor can prevent plugging of a forming carbon hardmask from occurring relatively too quickly.

Any suitable RF power conditions can be used to form a plasma in a processing chamber for controlled carbon deposition. In some examples, a plasma can be formed by application of a relatively higher frequency (HF) RF power. The HF RF power can comprise a frequency in a frequency band of 5 megahertz (MHz) or greater. In some examples, a relatively lower frequency (LF) RF power component also can be used. The terms “relatively higher frequency” and “relatively lower frequency” are with reference to one another. In some examples, the LF RF power can comprise a frequency in a frequency band of less than 5 MHz. HF RF and LF RF power levels can be varied in any suitable manner to help achieve a desired carbon film profile. In some examples, HF RF power can comprise power in a range of 100 W to 6,000 W. In some examples, LF RF power can comprise power in a range of 0 W to 5,000 W.

The HF RF and LF RF powers can have the same power level, or different power levels, in various examples.

The use of RF (HF and/or LF) power at relatively high power levels can favor a vertical growth of carbon films over lateral growth, as compared to lower RF power levels. Additionally, the use of LF RF power in addition to HF RF power can also favor vertical growth over lateral growth of carbon films, as compared to the use of HF RF power without LF RF power. LF RF power can cause more ion bombardment of a carbon film being deposited than HF RF power of a similar power level. Likewise, relatively higher RF power levels of either LF RF power or HF RF power can generate more ion bombardment of a carbon film being deposited. Such ion bombardment can cause etching of the carbon film being deposited that results in more vertical growth. The use of an etching agent with higher power RF and/or with LF RF power can further enhance vertical growth. While an etching agent can slow both vertical growth and horizontal growth, as vertical growth is faster than horizontal growth in this example, the etching agent still allows net vertical growth to be achieved while limiting horizontal growth.

As another example, the use of relatively higher levels of HF RF power and/or the use of LF RF power in addition to HF RF power can drive a passivating agent farther into a gap compared to the use of relatively lower levels of HF RF power without a LF RF power component. This is due to the ionization of the passivating agent in the plasma, followed by the ion bombardment of the substrate with the ionized passivating agent. This can drive the passivating agent farther into the gap. As a result, a depth within the gap at which carbon can grow on unpassivated surfaces is deeper than when a relatively lower RF power is used, and/or HF RF power without LF RF power.

Controlling the processing chamber conditions, as indicated at 306 of method 300, further can include one or more of controlling a flow rate of one or more gases in the gas mixture in the processing chamber, controlling a pressure in the processing chamber, or controlling a composition of the gas mixture in the processing chamber. In some examples, controlling a pressure in the processing chamber comprises controlling a pressure in the processing chamber in a range of 0.25 Torr to 120 Torr. In some examples, controlling a pressure in the processing chamber comprises controlling a pressure in the processing chamber in a range of 0.5 Torr to 20 Torr. In other examples, controlling a pressure in the processing chamber can comprise controlling a pressure in the processing chamber in a range of 0.25 Torr to 0.5 Torr, 0.5 Torr to 2 Torr, 2 Torr to 4 Torr, 4 Torr to 6 Torr, 6 Torr to 8 Torr, 8 Torr to 10 Torr, 10 Torr to 12 Torr, 12 Torr to 14 Torr, 14 Torr to 16 Torr, 16 Torr to 18 Torr, 18 Torr to 20 Torr, 20 Torr to 22 Torr, 22 Torr to 24 Torr, 24 Torr to 26 Torr, 26 Torr to 28 Torr, 28 Torr to 30 Torr, 30 Torr to 35 Torr, 35 Torr to 40 Torr, 40 Torr to 45 Torr, 45 Torr to 50 Torr, 50 Torr to 60 Torr, 60 Torr to 70 Torr, 70 Torr to 80 Torr, 80 Torr to 90 Torr, 90 Torr to 100 Torr, 100 Torr to 110 Torr, and 110 Torr to 120 Torr.

Controlling the composition of the gas mixture in the processing chamber can comprise, for example, selecting a carbon film precursor(s) for carbon deposition. Controlling the composition of the gas mixture further can include selecting one or more of a passivating agent(s), an etching agent(s), and/or inert gas(es). Controlling the composition of the gas mixture further can include selecting relative partial mole fractions of the one or more of the passivating agent(s) or the etching agent(s) in the gas mixture compared to other gases in the gas mixture. Relatively higher partial mole fractions of a passivating agent can result in a greater degree of passivation of the surfaces of the substrate due to more passivating agent adsorbing to the substrate. Likewise, relatively higher partial mole fractions of an etching agent can result in a relatively lower lateral growth rate compared to a vertical growth rate for a carbon film. In some examples, the composition of the gas mixture can include selecting a partial mole fraction of a carbon film precursor(s) and a partial mole fraction of an etching agent(s) so that the partial mole fraction ratio of carbon film precursor to etching agent is in a range of 10:1 to 1:8. In some examples, the composition of the gas mixture can include selecting a partial mole fraction of a carbon film precursor(s) and a partial mole fraction of a passivating agent(s) such that the partial mole fraction ratio of carbon film precursor to passivating agent is in a range of 10:1 to 1:8. In some examples, the composition of the gas mixture can include selecting a partial mole fraction of a carbon film precursor(s) and a partial mole fraction of passivating agent(s) and etching agent(s) such that the partial mole fraction ratio of carbon film precursor to passivating and etching agent mixture is in a range of 10:1 to 1:8. In some instances, the composition of the gas mixture can include selecting partial mole fractions of the gas mixture such that the partial mole fraction ratio of the carbon film precursor to a passivating agent, an etching agent, or both a passivating agent and an etching agent is in a range of 1:1 to 10:1. Ratios of the carbon film precursor to a passivating agent, an etching agent, or both a passivating agent and an etching agent, for example, can be in a range of 1:1 to 2:1, 2:1 to 3:1, 3:1 to 4:1, 4:1 to 5:1, 5:1 to 6:1, 6:1 to 7:1, 7:1 to 8:1, 8:1 to 9:1, and 9:1 to 10:1. In some instances, the ratio of carbon film precursor to a passivating agent, an etching agent, or both a passivating agent and an etching agent can be greater than 10:1 or less than 1:8.

Any suitable carbon film precursor can be used to controllably deposit a carbon film. Suitable carbon film precursors can include any carbon-containing compound that can be introduced into a processing chamber in gas phase to deposit a carbon film on a substrate surface using plasma-enhanced chemical-vapor deposition. Examples can include alkanes having a general formula CₙH₂ₙ₊₂ where n=1 to 10 (such as methane, ethane, etc.), alkenes having a general formula CₙH₂ₙ where n=2 to 10 (such as ethylene, propylene, etc.), alkynes having a general formula CₙH₂ₙ₋₂ where n=2 to 10 (such as acetylene, propyne, etc.), cyclic hydrocarbons (including aromatics), and alkyl amines and other nitrogen-containing compounds, that are gas-phase under processing conditions.

Suitable passivating agents can include any gas that can chemisorb or physisorb to a surface of the substrate and reduce a rate of carbon film growth on the substrate in a PECVD carbon deposition process. Suitable passivating agents can include one or more of molecular hydrogen (H₂), ammonia (NH₃), or sulfur dioxide (SO₂). By appropriately controlling conditions within the processing chamber, the substrate surface can be selectively passivated.

Suitable etching agents can include any material that remove a material from a substrate as the material is deposited by PECVD. Suitable etching agents can include one or more halogen-containing gases and/or one or more oxygen-containing gases. Where the etching agent includes a halogen-containing gas, the etching agent can include one or more of chlorine (Cl₂), fluorine (F₂), bromine (Br₂), iodine (I₂), nitrogen trifluoride (NF₃), boron trifluoride (BF₃), sulfur trifluoride (SF₃), sulfur hexafluoride (SF₆), or a CₓF_{y} species (for example, where x=2, 3, 4). Where the etching agent includes an oxygen-including gas, the etching agent can include one or more of carbon monoxide (CO), carbon dioxide (CO₂), carbon oxysulfide (COS), sulfur dioxide (SO₂), or molecular oxygen (O₂).

In some examples, an inert gas can be used to deliver the carbon film precursor(s) and the one or more of the passivating agent(s) or the etching agent(s). Any suitable inert gas can be used. Examples include one or more of helium (He), neon (Ne), argon (Ar), xenon (Xe), or krypton (Kr). Further, in some examples, molecular nitrogen (N₂) can be used as an inert gas.

As described above, another potential method to form a high aspect ratio gap in structures such as 3D integrated circuit mold stacks is to form the high aspect ratio gap in multiple stages. Each stage of the fabrication process can comprise depositing a deck of alternating layers of materials. Each stage can further comprise etching a gap through the deposited deck. For each deck, a respective gap can be aligned with a gap of each adjacent deck. A carbon hardmask plug can be formed in the gap of a deck after forming the gap in the deck and before depositing the alternating layers of a next deck. The carbon hardmask plug acts as an etch stop layer to prevent damage caused by etching of a gap in the next deck. The carbon hardmask plug can then be removed to join the gaps.

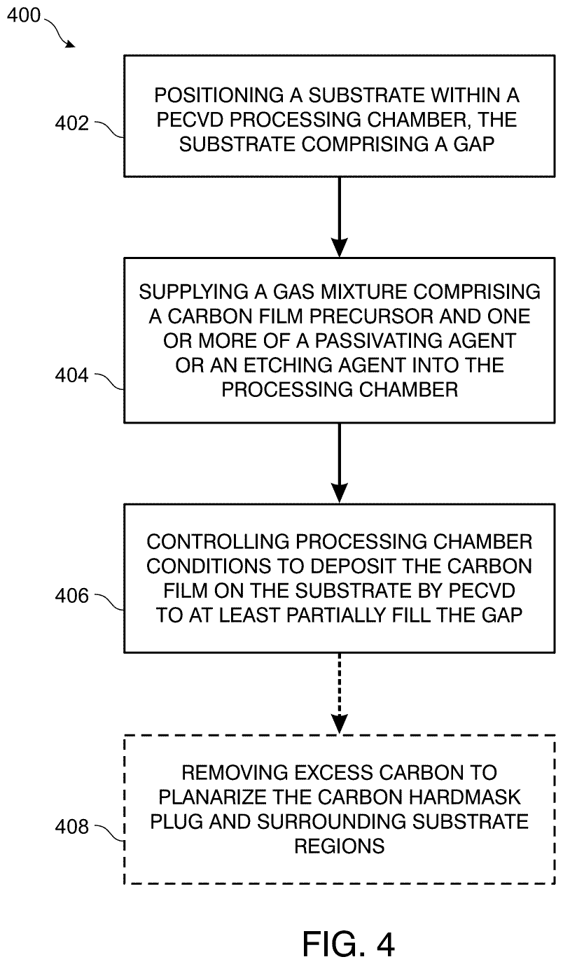

FIG. 4 shows a flow diagram depicting an example method 400 for forming a carbon hardmask plug in a gap on a substrate using PECVD. At 402, method 400 comprises positioning a substrate within a PECVD processing chamber, the substrate comprising a gap. In some examples, the gap can comprise a high aspect ratio gap formed in a deck in a 3D integrated circuit fabrication process. The deck can comprise alternating material layers, as described above. Examples of 3D integrated circuit fabrication processes can include 3D NAND fabrication processes, 3D NOR fabrication processes, and 3D DRAM fabrication processes. In other examples, the gap can comprise a gap formed in any other suitable integrated circuit manufacturing process.

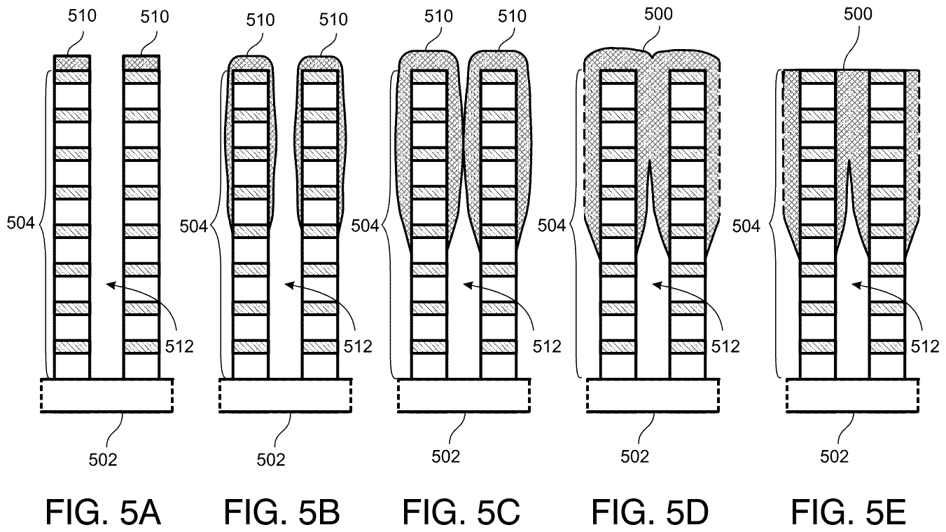

Continuing, at 404, method 400 comprises supplying a gas mixture comprising a carbon film precursor and one or more of a passivating agent or an etching agent into the processing chamber. Where both a passivating agent and an etching agent are used in method 400, the passivating agent and etching agent can be used simultaneously, or in sequence. At 406, method 400 comprises controlling processing chamber conditions to deposit the carbon film within the gap on the substrate by PECVD to at least partially fill the gap. In this example, a passivating agent can be used to passivate substrate surfaces closer to an opening of the gap. This can allow the carbon film precursor to reach deeper within the gap. As a result, the carbon hardmask plug can grow relatively deeper within the gap in comparison to carbon films deposited when the passivating agent is absent. Further, an etching agent can help to etch away carbon that deposits closer to the gap opening. The carbon etched in this manner can be converted to a volatile gas and removed, while carbon deposited deeper within the gap remains. In this manner, a carbon hardmask plug can be formed with sufficient thickness to withstand an etching of a gap in an adjacent deck of a 3D integrated circuit fabrication process. Example processing chamber conditions are described in more detail below with regard to FIGS. 5A-5E. Method 400 further can comprise, at 408, removing excess carbon to planarize the carbon hardmask plug and surrounding substrate regions.

FIGS. 5A-5E show structures formed in an example hardmask plug deposition process according to method 400. FIG. 5A shows a substrate 502 comprising a deck 504 of a mold stack. A hardmask 510 is disposed on deck 504. Hardmask 510 is eroded from the etching of a gap 512. As illustrated in FIGS. 5B-5D, a carbon hardmask plug 500 is deposited to protect gap 512 from etching of a gap within an adjacent deck (not shown in FIGS. 5A-5E). First referring to FIG. 5B, a carbon film precursor is used along with one or more of a passivating agent or an etching agent to cause carbon to deposit within gap 512. Examples of processing conditions are described in more detail below. Next referring to FIGS. 5C-5D, continued carbon deposition within gap 512 can form carbon hardmask plug 500 with a depth to avoid breakthrough caused by etching of an adjacent deck (not shown in FIGS. 5A-5E). The depth or thickness of the plug 500 can extend the entire or partial length of the deck 504 within gap 512, for example. The deposited plug 500 can extend across gap 512 and along one or more individual layers of deck 504 (e.g., ONON layers within the deck). One example is shown in FIGS. 5C-5E, where the depth of plug 500 extends across gap 512 and along 4 to 5 pairs of layers of deck 504. The plug 500 can extend a fewer number of individual layers, a greater number of individual layers, or the entire deck. In some instances, it may be desired to fill gap 512 only partially, but with sufficient depth and thickness to withstand a subsequent etch step in an adjacent deck (e.g., a second deck at the top or upper end of deck 504 and opposite the substrate 502 in FIGS. 5A-5E). As one example, the thickness of individual layers making up a deck can be in a range of 2 nm per layer to 50 nm per layer. As such, to plug or fill gap 512 at a depth that covers 4 to 5 layers and sufficient to withstand the subsequent etch step, such as shown in FIGS. 5D-5E, carbon plug 500 can be deposited and have a thickness ranging from 8 nm to 250 nm. Other thicknesses of plug 500 can be in a range of 8 nm to 20 nm, 20 nm to 50 nm, 50 nm to 100 nm, 100 nm to 150 nm, 150 nm to 200 nm, 200 nm to 250 nm, 250 nm to 300 nm, 300 nm to 400 nm, 400 nm to 500 nm, 500 nm to 600 nm, 600 nm to 700 nm, 700 nm to 800 nm, 800 nm to 900 nm, 900 nm to 1,000 nm, 20 nm to 1,000 nm, 20 nm to 200 nm, 200 nm to 500 nm, 500 nm to 1,000 nm, and 200 nm to 700 nm. Carbon hardmask plug 500 can then be planarized (for example, by chemical mechanical planarization (CMP)). FIG. 5E illustrates hardmask plug 500 after planarization. The planarized carbon hardmask plug 500 and surrounding substrate areas can provide a suitably even surface for forming an adjacent upper deck.

Any suitable processing conditions can be used to form hardmask plug 500. As mentioned above, the use of a passivating agent in a processing gas mixture can favor carbon film growth on surfaces relatively deeper within gap 512 (farther from an opening of gap 512) as compared to surfaces less deep within gap 512 (relatively closer to the opening of the gap 512). This is because the passivating agent can adsorb to surfaces at the relatively lesser depths within gap 512 at greater concentrations than those surfaces at relatively greater depths within gap 512, thereby decreasing the rate of carbon film growth at and near the opening of gap 512. As such, the carbon film can grow at a lesser rate on surfaces at relatively lesser depths (closer to an opening of gap 512) as compared to surfaces at relatively greater depths (farther from an opening of gap 512). Further, in some examples, an etching agent also can be used in the processing gas mixture. An etching agent can etch carbon on surfaces at relatively lesser depths within gap 512 (closer to an opening of gap 512) at a greater rate as compared to surfaces at relatively greater depths within gap 512 (farther from the opening of gap 512). This can cause slower carbon film growth at the surfaces at the relatively lesser depths within gap 512 compared to the surfaces at the relatively greater depths within gap 512. This is due at least to concentration of etching agent that interact with surfaces in the gap decreasing as a function of increasing depth within the gap. Example passivating agents and etching agents include those listed above.

A profile of hardmask plug 500 can also be controlled by controlling processing conditions used to form hardmask plug 500, such as for example controlling the power levels of the RF used to form the plasma in the processing chamber. As discussed above, increasing an RF power level (for either or both of HF RF power or LF RF power) can favor vertical growth of carbon films over lateral growth. Likewise, the use of LF plus RF power can favor vertical growth over lateral growth of carbon films, as compared to the use of HF RF power alone. As such, decreasing an RF power level can favor enhanced lateral carbon film growth within gap 512. As another example, the use of only HF RF power can favor carbon film growth deeper within gap 512, relative to carbon deposition using LF RF power and HF RF power. In various examples, HF RF power can be in a range of 25 W to 250 W, 250 W to 500 W, 500 W to 750 W, 750 W to 1,000 W, 1,000 W to 1,250 W, 1,250 W to 1,500W, 1,500 W to 1,750 W, 1,750 W to 2,000 W, 2,000 W to 2,250 W, 2,250 W to 2,500 W, 2,500 W to 2,750 W, and 2,750 W to 3,000 W. LF RF power can be in a range of 0 W to 25 W, 25 W to 50 W, 50 W to 75 W, 75 W to 100 W, 100 W to 200 W, 200 W to 300 W, 300 W to 400 W, and 400 W to 500 W. While the proceeding values can reflect HF and LF RF power ranges for a single chamber or station processing tool (e.g., processing tool 900), it should be understood the preceding values can be increased to reflect HF and LF RF values across a greater number of chamber or station processing tools. For example, HF and LF RF power for a dual chamber processing tool can be double or approximately double those HF and LF RF power ranges listed above with respect to a single chamber processing tool. Likewise, those HF and LF RF power ranges listed for a single chamber processing tool can be tripled for a three-chamber processing tool, quadrupled for a four-chamber processing tool, and so forth. For example, HF RF power for a four-chamber processing tool can be in a range of 100 W to 1,000 W, 1,000 W to 2,000 W, 2,000 W to 3,000 W, 3,000 W to 4,000 W, 4,000 W to 5,000 W, 5,000 W to 6,000 W, 6,000 W to 7,000 W, 7,000 W to 8,000 W, 8,000 W to 9,000 W, 9,000 W to 10,000 W, 10,000 W to 11,000 W, and 11,000 W to 12,000 W. Similarly, LF RF power for a four-chamber processing tool can be in a range of 0 W to 100 W, 100 W to 200 W, 200 W to 300 W, 300 W to 400 W, 400 W to 800 W, 800 W to 1,200 W, 1,200 W to 1,600 W, and 1,600 W to 2,000 W.

Another processing condition that can help to form a relatively thicker carbon hardmask plug can include relatively lesser processing gas flow rates. Such conditions can allow carbon-containing radical species formed by the plasma to reside within the processing chamber for a longer period of time as compared to using relatively higher processing gas flow rates. This can allow a greater quantity of carbon-containing radical species to reach surfaces at relatively greater depths within gap 512 than when using relatively higher flow rates.

Hardmask plug 500 can be deposited using various substrate temperatures. A substrate can be heated at least partially using a substrate heater integrated with a pedestal of a deposition system. In some examples, the substrate can be heated using a pedestal heater temperature of 250 to 800° C. Other example temperatures ranges include temperatures of 250-300° C., 300-350° C., 350 to 400° C., 400 to 450° C., 450 to 500° C., 500 to 550° C., 550 to 600° C., 600 to 650° C., 700 to 750° C., 750 to 800° C., 250 to 350° C., 350 to 450° C., 450 to 550° C., 550 to 650° C., 650 to 750° C., 200 to 400° C., 400 to 600° C., 600 to 800° C., 500 to 520° C., 520 to 540°C., 540 to 560° C., 560 to 580° C., 580 to 600° C., 600 to 620° C., 620 to 640° C., 640 to 660° C., 660 to 680° C., 680 to 700° C., 700 to 720° C., 720 to 740° C., 740 to 760° C., 760 to 780° C., and 780 to 800° C. Generally, higher temperatures can lead to higher reaction rates.

In some examples, a deposition tool showerhead can include an integrated showerhead heater. In such examples, the showerhead heater can be controlled to output heat to facilitate a hardmask plug deposition process. In some examples, the showerhead heater can be controlled to be heated to a temperature of 250 to 800° C. Other example temperatures ranges include temperatures of 250-300° C., 300-350° C., 350 to 400° C., 400 to 450° C., 450 to 500° C., 500 to 550° C., 550 to 600°C., 600 to 650° C., 700 to 750° C., 750 to 800° C., 250 to 350° C., 350 to 450° C., 450 to 550° C., 550 to 650° C., 650 to 750° C., 200 to 400° C., 400 to 600° C., 600 to 800° C., 500 to 520° C., 520 to 540° C., 540 to 560 ° C., 560 to 580° C., 580 to 600° C., 600 to 620°C., 620 to 640° C., 640 to 660° C., 660 to 680° C., 680 to 700° C., 700 to 720° C., 720 to 740° C., 740 to 760° C., 760 to 780° C., and 780 to 800° C. The heated showerhead can be made from any suitable material. For example, the showerhead can be an aluminum showerhead, an alloy showerhead, a composite showerhead, or a ceramic showerhead.

A carbon hardmask plug formed as illustrated in FIGS. 5A-5E can be deposited in a single deposition cycle. This can provide for a faster and less expensive carbon hardmask plug formation process than the use of alternating deposition and etching cycles.

The above-described conditions for depositing hardmask plug 500 can be used to deposit hardmask plug 500 at a range of deposition rates. The deposition rate can be a function of such parameters as a partial mole fraction of a carbon containing precursor, a total processing chamber pressure, a flow rate of the carbon containing precursor, a pedestal heater temperature, and a showerhead heater temperature. In some examples, the deposition rate can be 50-900 Å/min. In other examples, the deposition rate can be 50-100 Å/min, 100-150 Å/min, 150-200 Å/min, 200-250 Å/min., 250-300 Å/min, 350-400 Å/min, 400-450 Å/min, 450-500 Å/min, 500-550 Å/min, 550-600 Å/min, 600-650 Å/min, 650-700 Å/min, 700-750 Å/min, 750-800 Å/min, 800-850 Å/min, 850-900 Å/min, 50-150 Å/min, 150-250 Å/min, 250-350 Å/min, 350-450 Å/min, 450-550 Å/min, 550-650 Å/min, 650-750 Å/min, and 750-850 Å/min.

A carbon hardmask plug as disclosed can be suitably uniform when deposited using the example deposition conditions disclosed herein. Nonuniformity can be defined as a maximum range of thickness divided by an average thickness, expressed as a percentage. Example nonuniformities include nonuniformities within a range of 0-2.5%, 2.5-5%, 5-7.5%, 7.5-10%, 10-12.5%, 12.5-15%, 15-17.5%, 17.5-20%, 0-5%, 0-10%, 0-15%, and 0-20%.

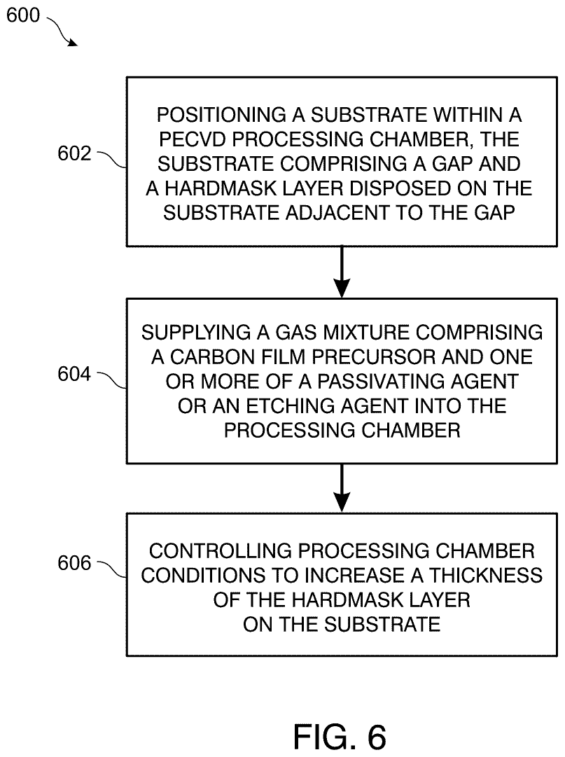

As described above, another possible method to etch a high aspect ratio gap can be to deposit an additional carbon layer over an eroded hardmask layer partway through the high aspect ratio gap etching process. However, as illustrated in FIGS. 1A-1E above, a carbon film used as an additional hardmask layer can close off a gap due to lateral growth. This can block further etching of the gap. Thus, to avoid closing off or obstructing the gap when depositing the additional hardmask layer by PECVD, one or more of an etching agent or a passivating agent can be used in the PECVD deposition. FIG. 6 shows a flow diagram depicting an example method 600 for the vertical thickening of a carbon hardmask using PECVD. As indicated at 602, method 600 comprises positioning a substrate within a PECVD processing chamber. The substrate comprises a gap and a hardmask layer disposed on the substrate adjacent the gap. The hardmask comprises a pattern that controls the location of the gap. In some examples, the gap can comprise a high aspect ratio gap formed in a deck in a 3D integrated circuit fabrication process. The deck can comprise alternating material layers, as described above. Examples of 3D integrated circuit fabrication processes can include 3D NAND fabrication processes, 3D NOR fabrication processes, and 3D DRAM fabrication processes. In other examples, the gap can comprise a gap formed in any other suitable integrated circuit manufacturing process. Continuing, at 604, method 600 comprises supplying a gas mixture comprising a carbon film precursor and one or more of a passivating agent or an etching agent into the processing chamber. For example, the use of an etching agent can favor vertical carbon film growth over lateral carbon film growth. This can help to thicken the carbon hardmask while not occluding the gap with lateral growth. In some examples, the use of a passivating agent can passivate sites along the sidewall(s) of a carbon film as it grows. This can help to favor vertical hardmask growth over lateral hardmask growth. Continuing, at 606, method 600 comprises controlling processing chamber conditions to increase a thickness of the hardmask layer on the substrate.

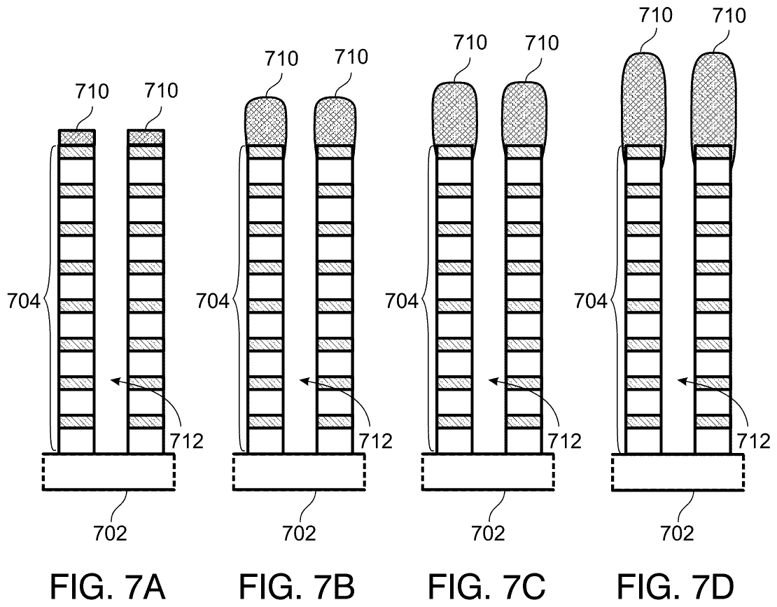

FIGS. 7A-7D show structures formed in an example carbon hardmask deposition process according to method 600. FIG. 7A shows a substrate 702 comprising a deck 704 of a mold stack. A hardmask 710 is disposed on deck 704. Hardmask 710 is eroded from the etching of a gap 712. Thus, as illustrated in FIGS. 7B-7D, additional carbon is deposited on hardmask 710 to thicken hardmask 710. Due to the sticking coefficient of the carbon film precursor, additive carbon deposition can be readily carried out on upper surfaces of the substrate, compared to surfaces deeper within a gap. In this example an etching agent can be used in a gas mixture used for depositing the carbon film by PECVD to reduce the lateral carbon film growth rate compared to the vertical growth rate. The etching agent removes some deposited carbon as hardmask 710 is being thickened. However, net carbon growth occurs. The combination of the net carbon deposition combined with the etching of some deposited carbon can lead to more vertical growth relative to lateral growth (i.e., vertical growth that is slightly rounded or only moderately tapered). Example processing conditions to help enhance vertical growth over lateral growth are described in more detail below. The vertical thickening of carbon hardmask 710 without occluding gap 712 can allow additional etching of gap 712 to be performed while protecting surrounding regions of deck 704.

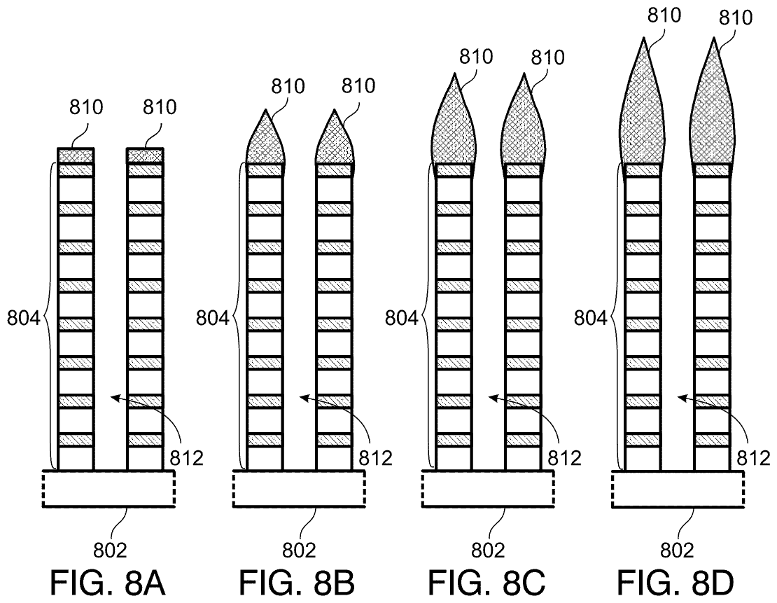

FIGS. 8A-8D show structures formed by another example carbon hardmask thickening process according to method 600. FIG. 8A shows a substrate 802 comprising a deck 804 of a mold stack. A hardmask 810 is disposed on deck 804. Hardmask 810 is eroded from the etching of a gap 812. As illustrated in FIGS. 8B-8D, additional carbon hardmask 810 is deposited on deck 804 under conditions configured to lead to the growth of additional carbon with a tapered profile. First referring to FIG. 8B, a carbon film precursor is used along with an etching agent to cause carbon to deposit onto hardmask 810 on an upper surface of deck 804. As mentioned above, the etching agent removes some deposited carbon as hardmask 710 is being thickened. However, net carbon growth occurs. In FIGS. 8A-D, one or more of a greater concentration of etching agent, a different etching agent, or different processing chamber conditions can be used compared to FIGS. 7A-7D to achieve the tapered profile. Examples of processing conditions are described in more detail below. Next referring to FIGS. 8C-8D, continued carbon deposition on deck 704 can form an additional carbon hardmask exhibiting even more vertical growth relative to lateral growth (i.e., vertical growth that is moderately or highly tapered), so that the additional carbon hardmask avoids occluding access to gap 812 for subsequent etching processes, while still protecting deck 804.

Any suitable processing conditions can be used to increase the thickness of a hardmask through additive carbon deposition. Suitable processing conditions to increase the thickness of an additive hardmask can include one or more of relatively greater RF power levels, the use of LF RF power, or relatively higher processing gas flow rates.

In various examples, HF RF power used in an additional carbon deposition process as disclosed can be in a range of 25 W to 250 W, 250 W to 500 W, 500 W to 750 W, 750 W to 1,000 W, 1,000 W to 1,250 W, 1,250 W to 1,500 W, 1,500 W to 1,750 W, 1,750 W to 2,000 W, 2,000 W to 2,250 W, 2,250 W to 2,500 W, 2,500 W to 2,750 W, and 2,750 W to 3,000 W. LF RF power can be in a range of 0 W to 25 W, 25 W to 50 W, 50 W to 75 W, 75 W to 100 W, 100 W to 200 W, 200 W to 300 W, 300 W to 400 W, and 400 W to 500 W. While the proceeding values can reflect HF and LF RF power ranges for a single chamber or station processing tool (e.g., processing tool 900), it should be understood the preceding values can be increased to reflect HF and LF RF values across a greater number of chamber or station processing tools. For example, HF and LF RF power for a dual chamber processing tool can be double or approximately double those HF and LF RF power ranges listed above with respect to a single chamber processing tool. Likewise, those HF and LF RF power ranges listed for a single chamber processing tool can be tripled for a three-chamber processing tool, quadrupled for a four-chamber processing tool, and so forth. For example, HF RF power for a four-chamber processing tool can be in a range of 100 W to 1,000 W, 1,000 W to 2,000 W, 2,000 W to 3,000 W, 3,000 W to 4,000 W, 4,000 W to 5,000 W, 5,000 W to 6,000 W, 6,000 W to 7,000 W, 7,000 W to 8,000 W, 8,000 W to 9,000 W, 9,000 W to 10,000 W, 10,000 W to 11,000 W, and 11,000 W to 12,000 W. Similarly, LF RF power for a four-chamber processing tool can be in a range of 0 W to 100 W, 100 W to 200 W, 200 W to 300 W, 300 W to 400 W, 400 W to 800 W, 800 W to 1,200 W, 1,200 W to 1,600 W, and 1,600 W to 2,000 W.

Further, a pressure in a processing chamber used to perform an additional carbon deposition process as disclosed can be controlled to be in a range of 0.25 Torr to 120 Torr. In some examples, controlling a pressure in the processing chamber comprises controlling a pressure in the processing chamber in a range of 0.5 Torr to 20 Torr. In other examples, controlling a pressure in the processing chamber can comprise controlling a pressure in the processing chamber in a range of 0.25 Torr to 0.5 Torr, 0.5 Torr to 2 Torr, 2 Torr to 4 Torr, 4 Torr to 6 Torr, 6 Torr to 8 Torr, 8 Torr to 10 Torr, 10 Torr to 12 Torr, 12 Torr to 14 Torr, 14 Torr to 16 Torr, 16 Torr to 18 Torr, 18 Torr to 20 Torr, 20 Torr to 22 Torr, 22 Torr to 24 Torr, 24 Torr to 26 Torr, 26 Torr to 28 Torr, 28 Torr to 30 Torr, 30 Torr to 35 Torr, 35 Torr to 40 Torr, 40 Torr to 45 Torr, 45 Torr to 50 Torr, 50 Torr to 60 Torr, 60 Torr to 70 Torr, 70 Torr to 80 Torr, 80 Torr to 90 Torr, 90 Torr to 100 Torr, 100 Torr to 110 Torr, and 110 Torr to 120 Torr.

In some examples, selecting the composition of the gas mixture used to deposit additional carbon as disclosed can include selecting a partial mole fraction of a carbon film precursor(s) and a partial mole fraction of passivating agent(s) and/or etching agent(s) such that the partial mole fraction ratio of carbon film precursor to passivating and etching agent mixture is in a range of 10:1 to 1:8. In some instances, the composition of the gas mixture can include selecting partial mole fractions of the gas mixture such that the partial mole fraction ratio of the carbon film precursor to a passivating agent, an etching agent, or both a passivating agent and an etching agent is in a range of 1:1 to 10:1. Ratios of the carbon film precursor to a passivating agent, an etching agent, or both a passivating agent and an etching agent, for example, can be in a range of 1:1 to 2:1, 2:1 to 3:1, 3:1 to 4:1, 4:1 to 5:1, 5:1 to 6:1, 6:1 to 7:1, 7:1 to 8:1, 8:1 to 9:1, and 9:1 to 10:1. In some instances, the ratio of carbon film precursor to a passivating agent, an etching agent, or both a passivating agent and an etching agent can be greater than 10:1 or less than 1:8.

Additional carbon as illustrated in FIGS. 7A-7D and 8A-8D can be deposited using various substrate heater temperatures. As described above, in some examples, the substrate can be heated using a pedestal heater temperature of 250 to 800° C. Other example temperatures ranges include temperatures of 250-300° C., 300-350° C., 350 to 400° C., 400 to 450° C., 450 to 500° C., 500 to 550° C., 550 to 600° C., 600 to 650° C., 700 to 750° C., 750 to 800° C., 250-350° C., 350 to 450° C., 450 to 550° C., 550 to 650° C., 650 to 750° C., 200 to 400° C., 400 to 600° C., 600 to 800° C., 500 to 520° C., 520 to 540° C., 540 to 560° C., 560 to 580° C., 580 to 600° C., 600 to 620° C., 620 to 640° C., 640 to 660° C., 660 to 680° C., 680 to 700° C., 700 to 720° C., 720 to 740° C., 740 to 760° C., 760 to 780° C., and 780 to 800° C. Generally, higher temperatures can lead to higher reaction rates.

In some examples, a deposition tool showerhead can include an integrated showerhead heater. In such examples, the showerhead heater can be controlled to output heat to facilitate an additional carbon deposition process. In some examples, the showerhead heater can be controlled to be heated to a temperature of 250 to 800° C. Other example temperatures ranges include temperatures of 250-300° C., 300-350° C., 350 to 400° C., 400 to 450° C., 450 to 500° C., 500 to 550° C., 550 to 600° C., 600 to 650° C., 700 to 750° C., 750 to 800° C., 250 to 350° C., 350 to 450° C., 450 to 550° C., 550 to 650° C., 650 to 750° C., 200 to 400° C., 400 to 600° C., 600 to 800° C., 500 to 520° C., 520 to 540° C., 540 to 560° C., 560 to 580° C., 580 to 600° C., 600 to 620° C., 620 to 640° C., 640 to 660° C., 660 to 680° C., 680 to 700° C., 700 to 720° C., 720 to 740° C., 740 to 760° C., 760 to 780° C., and 780 to 800° C.

Such conditions also can be adjusted to create the more tapered profile of the additional carbon as illustrated in FIGS. 8A-8D relative to the less tapered profile illustrated in FIGS. 7A-7D. For example, the more tapered profile can be achieved by employing one or more of a greater concentration of etching agent, a different etching agent, a relatively higher HF RF power level, and/or the use of an LF RF component. Example etching agents that may be used for forming the tapered profile include halogen-containing etching agents. Example halogen-containing etching agents include nitrogen trifluoride (NF₃), sulfur trifluoride (SF₃), sulfur hexafluoride (SF₆), halocarbon gases, halogen acids (hydrofluoric acid (HF), hydrochloric acid (HCl), hydrobromic acid (HBr), hydroiodic acid (HI)), and halogen gases (F₂, Cl₂, Br₂, I₂).

The example processing conditions described above can form additional carbon as illustrated in FIGS. 7A-7D and 8A-8D having any suitable height. In various examples, for a 100 nm hole pattern (spacing between centers of adjacent holes), the height of the additional carbon over a carbon hardmask layer on which the additional carbon is deposited can be 100 -1100 nm. In other examples, the additional carbon can have a height of 100-150 nm, 150-200 nm, 200-250 nm, 250-300 nm, 300-350 nm, 350-400 nm, 400-450 nm, 450-500 nm, 500-550 nm, 550-600 nm, 600-650 nm, 650-700 nm, 700-750 nm, 750-800 nm, 800-850 nm, 850-900 nm, 900-950 nm, 950-1000 nm, 100-300 nm, 300-500 nm, 500-700 nm, and 700-900 nm. It will be understood that a thickness of the additional carbon can be at least partially determined based upon a selectivity and duration of an etching process to be subsequently performed.

Further, the additional carbon can have any suitable amount of taper compared to a width of the of the carbon hardmask on which the additional carbon is deposited. The taper can be measured as a difference in width at a specified height above a surface of the carbon hardmask on which the additional carbon is deposited compared to the width of the carbon hardmask. This measurement also can be referred to as neck shrink. In various examples, for a 100 nm hole pattern, the neck shrink can have a value of less than 5 nm at a height of 500 nm, 5-10 nm at 500 nm, 10-5 nm at 500 nm, 15-20 nm at 500 nm, 20-25 nm at 500 nm, 25-30 nm at 500 nm, 30-35 nm at 500 nm, 35-40 nm at 500 nm, 40-45 nm at 500 nm, 45-50 nm at 500 nm, 0-20 nm at 500 nm, 20-40 nm at 500 nm, and 40-50 nm at 500 nm. In further examples, the neck shrink can have a value of less than 5 nm at a height of 300nm, 5-10 nm at 300 nm, 10-15 nm at 300 nm, 15-20 nm at 300 nm, 20-25 nm at 300 nm, 25-30 nm at 300 nm, 30-35 nm at 300 nm, 35-40 nm at 300 nm, 40-45 nm at 300 nm, 45-50 nm at 300 nm, 0-20 nm at 300 nm, 20-40 nm at 300 nm, and 40-50 nm at 300 nm.

Additional carbon as illustrated in FIGS. 7A-7D and 8A-8D can be deposited in a single deposition cycle. This can provide for a faster and less expensive carbon hardmask plug formation process than the use of alternating deposition and etching cycles.

The above-described conditions for depositing additional carbon, such as illustrated FIGS. 7A-7D and 8A-8D, can provide for deposition at a range of deposition rates. As mentioned above, the deposition rate can be a function of such parameters as a partial mole fraction of a carbon containing precursor, a total processing chamber pressure, a flow rate of the carbon containing precursor, a pedestal heater temperature, and a showerhead heater temperature. In some examples, the deposition rate can be 50-900 Å/min. In other examples, the deposition rate can be 50-100 Å/min, 100-150 Å/min, 150-200 Å/min, 200-250 Å/min., 250-300 Å/min, 350-400 Å/min, 400-450 Å/min, 450-500 Å/min, 500-550 Å/min, 550-600 Å/min, 600-650 Å/min, 650-700 Å/min, 700-750 Å/min, 750-800 Å/min, 800-850 Å/min, 850-900 Å/min, 50-150 Å/min, 150-250 Å/min, 250-350 Å/min, 350-450 Å/min, 450-550 Å/min, 550-650 Å/min, 650-750 Å/min, and 750-850 Å/min.

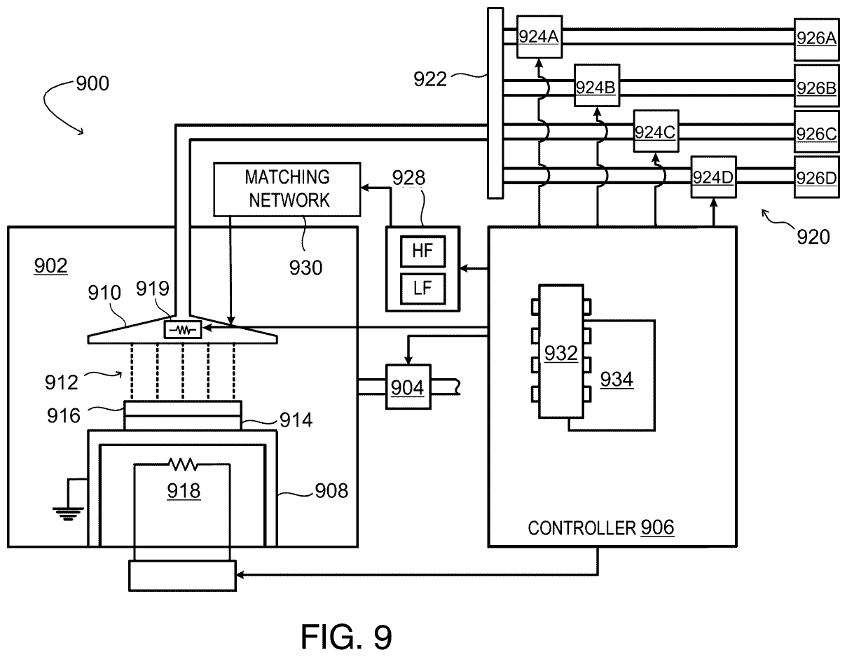

Additional carbon deposited over a carbon hardmask can be suitably uniform when deposited using the example deposition conditions disclosed herein. Nonuniformity can be defined as a maximum range of thickness divided by an average thickness, expressed as a percentage. Example nonuniformities include nonuniformities within a range of 0-2.5%, 2.5-5%, 5-7.5%, 7.5-10%, 10-12.5%, 12.5-15%, 15-17.5%, 17.5-20%, 20-22.5%, 22.5-25%, 25-27.5%, 27.5-30%, 0-5%, 0-10%, 0-15%, 0-20%, and 0-30%. FIG. 9 shows an example processing tool 900 that can be used to form a carbon film according to the present disclosure. It will be understood that tools other than processing tool 900 can be used to practice the example methods disclosed herein. Any suitable processing tool can be used. In some examples, processing tool 900 can include at least one processing chamber or station. In some examples, processing tool 900 can be a single station processing tool, a dual station processing tool, a triple station processing tool, or a quad station processing tool.

Processing tool 900 takes the form of a PECVD tool comprising a deposition chamber 902. Deposition chamber 902 is configured to be maintained at a reduced pressure during deposition processes using a vacuum pump system 904 comprising one or more pumps. Vacuum pump system 904 is in electrical communication with a controller 906 configured to output control signals to vacuum pump system 904 and other components described below.

Processing tool 900 further comprises a pedestal electrode 908, a pedestal 914, a showerhead 910 that acts as a counter electrode to pedestal electrode 908. Pedestal electrode 908 and showerhead 910 are separated by an interelectrode space that defines a discharge gap 912. A pedestal 914 is arranged on or integrated with pedestal electrode 908, and a substrate 916 (in this example, a wafer) is shown as arranged on pedestal 914. In the illustrated example, a heater 918 is positioned below pedestal electrode 908. The heater 918 is controlled using control signals from controller 906, so as to maintain the pedestal electrode 908 at a desired setpoint temperature. Further, showerhead 910 also optionally can comprise a showerhead heater 919.

Processing tool 900 further comprises a gas flow control system 920 configured to flow a mixture of gases into deposition chamber 902 through showerhead 910 at reduced pressure. Gas flow control system 920 comprises a manifold 922 and a series of mass-flow and/or volume-flow controllers 924A, 924B, 924C, and 924D, which provide a metered flow of each of a plurality of gases from gas sources, as controlled by control signals from controller 906. For example, processing tool 900 further comprises a carbon film precursor source 926A. Carbon film precursor source 926A can comprise one or more carbon film precursors. Example carbon precursors can include alkanes having a general formula CₙH₂ₙ₊₂ where n=1 to 10 (such as methane, ethane, etc.), alkenes having a general formula CₙH₂ₙ where n=2 to 10 (such as ethylene, propylene, etc.), alkynes having a general formula CₙH₂ₙ₋₂ where n=2 to 10 (such as acetylene, propyne, etc.), cyclic hydrocarbons (including aromatics) , and alkyl amines and other nitrogen-containing compounds, that are gas-phase under processing conditions.

Processing tool 900 further can comprise a passivating agent source 926B. Passivating agent source 926B can comprise one or more passivating agents. Example passivating agents can include hydrogen-containing molecules. Example hydrogen-containing molecules that can be used as passivating agents include molecular hydrogen (H₂), and ammonia (NH₃).

Processing tool 900 also can comprise an etching agent source 926C. Etching agent source 926C can comprise any suitable etching agent. Example etching agents can include halogen-containing and/or oxygen-containing gases. Example halogen-containing etching agents can include chlorine (Cl₂), fluorine (F₂), bromine (Br₂), iodine (I₂), nitrogen trifluoride (NF₃), boron trifluoride (BF₃), sulfur hexafluoride (SF₆), and halocarbon species having a general formula CₐH_{b}X_{c} species, where X comprises one or more of fluorine, chlorine, bromine, or iodine and where a=1-10). Example oxygen-containing etching agents include, but are not limited to, carbon monoxide (CO), carbon dioxide (CO₂), carbon oxysulfide (COS), sulfur dioxide (SO₂), and molecular oxygen (O₂).

Processing tool 900 additionally comprises an inert gas source 926D. Example inert gases can include nitrogen (N₂), helium (He), and/or argon (Ar), e.g., as one or more diluent gases and/or purging gases. While four gas sources 926A, 926B, 926C, 926D are shown in the example of FIG. 9, any other suitable number of gas sources and associated flow controllers can be used in other examples.

Processing tool 900 further comprises a power supply 928 configured to drive a current through the discharge gap between showerhead 910 and pedestal electrode 908 to form a plasma. To this end, power supply 928 receives control signals from the controller 906 to control various aspects of the current driven. Power supply 928 includes one or more radiofrequency (RF) power supplies configured to drive RF current through the discharge gap. Different RF power supplies can be provided for different RF bands. Such bands can include, for example, a high-frequency (HF) band comprising frequencies of 5 megahertz (MHz) or greater, and a low-frequency (LF) band comprising frequencies less than 5 MHz. The current driven through the discharge gap 912 can support a carbon-depositing plasma comprising ions made by ionization of the mixture of gases in the deposition chamber 902. Processing tool 900 further comprises a matching network 930 disposed between power supply 928 and showerhead 910 for impedance matching of the RF power supply.

As mentioned above, controller 906 of processing tool 900 is coupled operatively to vacuum pump system 904, heater 918, showerhead heater 919, flow controllers 924, power supply 928, as well as to other controllable components of the processing tool 900. Controller 906 comprises at least one processor 932 and memory 934. Memory 934 holds instructions executable by the at least one processor 932 to direct controller 906 to enact any of the control functions associated with the fabrication processes disclosed herein, among other functions. In some examples, controller 906 can be local to other components of fabrication tool 900. In other examples, controller 906 can be located remotely to other components of fabrication tool 900. In yet other examples, controller 906 can be distributed between local and remote locations with reference to fabrication tool 900.

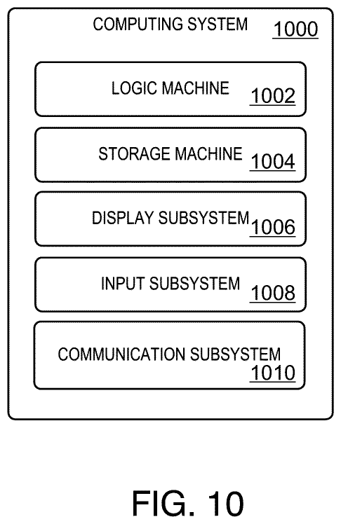

FIG. 10 schematically shows a non-limiting example of a computing system 1000 that can enact one or more of the methods and processes described above. Computing system 1000 is shown in simplified form. Computing system 1000 can take the form of one or more personal computers, server computers, and computers integrated with processing equipment, as examples. Controller 906 is an example of computing system 1000.

Computing system 1000 includes a logic machine 1002 and a storage machine 1004. Computing system 1000 can optionally include a display subsystem 1006, input subsystem 1008, communication subsystem 1010, and/or other components not shown in FIG. 10.

Logic machine 1002 includes one or more physical devices configured to execute instructions. For example, the logic machine can be configured to execute instructions that are part of one or more applications, services, programs, routines, libraries, objects, components, data structures, or other logical constructs. Such instructions can be implemented to perform a task, implement a data type, transform the state of one or more components, achieve a technical effect, or otherwise arrive at a desired result.

The logic machine can include one or more processors configured to execute software instructions. Additionally or alternatively, the logic machine can include one or more hardware or firmware logic machines configured to execute hardware or firmware instructions. Processors of the logic machine can be single-core or multi-core, and the instructions executed thereon can be configured for sequential, parallel, and/or distributed processing. Individual components of the logic machine optionally can be distributed among two or more separate devices, which can be remotely located and/or configured for coordinated processing. Aspects of the logic machine can be virtualized and executed by remotely accessible, networked computing devices configured in a cloud-computing configuration.

Storage machine 1004 includes one or more physical devices configured to hold instructions executable by the logic machine to implement the methods and processes described herein. When such methods and processes are implemented, the state of storage machine 1004 can be transformed—e.g., to hold different data.

Storage machine 1004 can include removable and/or built-in devices. Storage machine 1004 can include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 1004 can include volatile, nonvolatile, dynamic, static, read/write, read-only, random-access, sequential-access, location-addressable, file-addressable, and/or content-addressable devices. It will be appreciated that storage machine 1004 includes one or more physical devices. However, aspects of the instructions described herein alternatively can be propagated by a communication medium (e.g., an electromagnetic signal, an optical signal, etc.) that is not held by a physical device for a finite duration. Aspects of logic machine 1002 and storage machine 1004 can be integrated together into one or more hardware-logic components. Such hardware-logic components can include field-programmable gate arrays (FPGAs), program-and application-specific integrated circuits (PASIC/ASICs), program-and application-specific standard products (PSSP/ASSPs), system-on-a-chip (SOC), and complex programmable logic devices (CPLDs), for example.

When included, display subsystem 1006 can be used to present a visual representation of data held by storage machine 1004. This visual representation can take the form of a graphical user interface (GUI). As the herein described methods and processes change the data held by the storage machine, and thus transform the state of the storage machine, the state of display subsystem 1006 can likewise be transformed to visually represent changes in the underlying data. Display subsystem 1006 can include one or more display devices utilizing virtually any type of technology. Such display devices can be combined with logic machine 1002 and/or storage machine 1004 in a shared enclosure, or such display devices can be peripheral display devices.

When included, input subsystem 1008 can comprise or interface with one or more user-input devices such as a keyboard, mouse, or touch screen. In some examples, the input subsystem can comprise or interface with selected natural user input (NUI) componentry. Such componentry can be integrated or peripheral, and the transduction and/or processing of input actions can be handled on-or off-board. Example NUI componentry can include a microphone for speech and/or voice recognition, and an infrared, color, stereoscopic, and/or depth camera for machine vision and/or gesture recognition.

When included, communication subsystem 1010 can be configured to communicatively couple computing system 1000 with one or more other computing devices. Communication subsystem 1010 can include wired and/or wireless communication devices compatible with one or more different communication protocols. As non-limiting examples, the communication subsystem can be configured for communication over a wireless telephone network, or a wired or wireless local- or wide-area network. In some examples, the communication subsystem can allow computing system 1000 to send and/or receive messages to and/or from other devices over a network such as the Internet.

It will be understood that the configurations and/or approaches described herein are presented as examples, and that these specific examples or examples are not to be considered in a limiting sense, because numerous variations are possible. The specific routines or processes described herein can represent one or more of any number of processing strategies. As such, various acts illustrated and/or described can be performed in the sequence illustrated and/or described, in other sequences, in parallel, or omitted. Likewise, the order of the above-described processes can be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method of forming a carbon film on a substrate, the method comprising:
positioning a substrate within a plasma-enhanced chemical vapor deposition (PECVD) processing chamber;
supplying a gas mixture into the processing chamber, the gas mixture comprising
a carbon film precursor, and
a passivating agent, an etching agent, or both a passivating agent and an etching agent; and
controlling at least one processing chamber condition to deposit a carbon film on the substrate.

2. The method of claim 1, wherein the substrate comprises a recessed feature extending into the substrate, and wherein the carbon film at least partially fills the recessed feature.

3. The method of claim 2, wherein the recessed feature is a gap in a 3D NAND memory structure, and the carbon film is a carbon hardmask plug.

4. The method of claim 2, wherein the passivating agent or the etching agent comprises a hydrogen-containing molecule.

5. The method of claim 4, wherein the hydrogen-containing molecule comprises hydrogen (H₂) or ammonia (NH₃).

6. The method of claim 1, wherein the passivating agent or the etching agent comprises boron trifluoride (BF₃), carbon monoxide (CO), carbon dioxide (CO₂), carbon oxysulfide (COS), molecular oxygen (O₂), nitrogen trifluoride (NF₃), sulfur dioxide (SO₂), sulfur hexafluoride (SF₆), a halocarbon gas, a halogen acid (hydrofluoric acid (HF), hydrochloric acid (HCl), hydrobromic acid (HBr), hydroiodic acid (HI)), a halogen gas (F₂, Cl₂, Br₂, I₂), or a combination of two or more thereof.

7. The method of claim 1, wherein the carbon film is an additional carbon layer deposited over an eroded hardmask layer.

8. The method of claim 1, wherein the carbon film has a tapered profile.

9. The method of claim 1, wherein controlling the at least one processing chamber condition comprises applying a first radiofrequency (RF) power and a second RF power to form a plasma, wherein the first RF power has a lower frequency than the second RF power.

10. The method of claim 1, wherein the carbon film precursor comprises a precursor molecule that is in a gas phase in the processing chamber, the precursor molecule comprising an alkane having a general formula CₙH₂ₙ₊₂ where n=1 to 10, an alkene having a general formula CₙH₂ₙ where n=2 to 10, an alkyne having a general formula CₙH₂ₙ₋₂ where n=2 to 10, an alkyl amine, a cyclic hydrocarbon, or a combination of two or more thereof.

11. The method of claim 10, wherein the carbon film precursor comprises acetylene, propylene, methane, or a combination of two or more thereof.

12. A processing tool, comprising:
a processing chamber;
a radiofrequency (RF) power supply;
one or more processing gas sources comprising
a carbon film precursor source comprising a carbon film precursor; and
a passivating agent source comprising a passivating agent, an etching agent source comprising an etching agent, or a passivating agent source and an etching agent source;
flow control hardware fluidly connecting the one or more processing gas sources and the processing chamber; and
a controller configured to:
control the flow control hardware to supply a gas mixture comprising the carbon film precursor and one or more of the passivating agent or the etching agent into the processing chamber;
control the RF power supply to form a plasma in the processing chamber; and
control processing chamber conditions to deposit a carbon film on a substrate situated within the processing chamber by plasma enhanced chemical vapor deposition (PECVD).

13. The processing tool of claim 12, wherein the passivating agent or the etching agent comprises a hydrogen-containing molecule.

14. The processing tool of claim 13, wherein the hydrogen-containing molecule comprises one or more of molecular hydrogen (H₂), or ammonia (NH₃).

15. The processing tool of claim 12, wherein the passivating agent or the etching agent comprises one or more of boron trifluoride (BF₃), carbon monoxide (CO), carbon dioxide (CO₂), carbon oxysulfide (COS), molecular oxygen (O₂), nitrogen trifluoride (NF₃), sulfur dioxide (SO₂), sulfur hexafluoride (SF₆), a halocarbon gas, a halogen acid (hydrofluoric acid (HF), hydrochloric acid (HCl), hydrobromic acid (HBr), hydroiodic acid (HI)), halogen gas (F₂, Cl₂, Br₂, I₂), or a combination of two or more thereof.

16. The processing tool of claim 12, wherein the controller is configured to form the plasma within the processing chamber by controlling the RF power supply to apply a first RF power and a second RF power, wherein the first RF power has a lower frequency than the second RF power.

17. The processing tool of claim 12, wherein the carbon film precursor comprises a precursor molecule that is in a gas phase in the processing chamber conditions, the precursor molecule comprising one or more of an alkane having a general formula CₙH₂ₙ₊₂ where n=1 to 10, an alkene having a general formula CₙH₂ₙ where n=2 to 10, an alkyne having a general formula CₙH₂ₙ₋₂ where n=2 to 10, an alkyl amine, a cyclic hydrocarbon, or a combination of two or more thereof.

18. A method of thickening a carbon hardmask layer on a substrate, the method comprising:
positioning a substrate within a plasma-enhanced chemical vapor deposition (PECVD) processing chamber, the substrate comprising a recessed feature extending into the substrate, and a carbon hardmask layer disposed on a surface of the substrate and adjacent to the recessed feature;
supplying a gas mixture comprising a carbon film precursor and one or more of a passivating agent or an etching agent into the processing chamber; and
controlling processing chamber conditions to deposit an additional carbon layer on the carbon hardmask layer.

19. The method of claim 18, wherein the additional carbon layer deposited on the hardmask layer has a tapered profile.

20. The method of claim 18, wherein the passivating agent or the etching agent comprises hydrogen (H₂), ammonia (NH₃), boron trifluoride (BF₃), carbon monoxide (CO), carbon dioxide (CO₂), carbon oxysulfide (COS), molecular oxygen (O₂), nitrogen trifluoride (NF₃), sulfur dioxide (SO₂), sulfur hexafluoride (SF₆), a halocarbon gas, a halogen acid (hydrofluoric acid (HF), hydrochloric acid (HCl), hydrobromic acid (HBr), hydroiodic acid (HI)), a halogen gas (F₂, Cl₂, Br₂, I₂), or a combination of two or more thereof.
